(19) United States
(12) Patent Application Publication
(10) Pub. No.: US 2025/0261430 A1
(43) Pub. Date: Aug. 14, 2025

(54) SEMICONDUCTOR DEVICE

(71) Applicant: Mitsubishi Electric Corporation, Tokyo (JP)

(72) Inventors: Yusuke MIYATA, Tokyo (JP); Yuki HARAGUCHI, Tokyo (JP); Haruhiko MINAMITAKE, Tokyo (JP); Taiki HOSHI, Tokyo (JP); Shinya AKAO, Tokyo (JP); Hidenori KOKETSU, Tokyo (JP)

(73) Assignee: Mitsubishi Electric Corporation, Tokyo (JP)

(21) Appl. No.: 18/967,117

(22) Filed: Dec. 3, 2024

(30) Foreign Application Priority Data
Feb. 9, 2024 (JP) 2024-018390

(51) Int. Cl. H10D 64/66; H10D 64/27

(52) U.S. Cl. CPC H10D 64/668; H10D 64/514; H10D 64/518

(57) ABSTRACT

A semiconductor device includes a semiconductor substrate, an alloy layer containing a constituent element of the semiconductor substrate as a main component and an upper metal layer formed on the alloy layer. A plurality of minute regions containing an inert gas is discretely arranged at an interface between the alloy layer and the upper metal layer. Not less than 90% of a plurality of the minute regions has an arc shape whose opening is the widest portion.

### BACKGROUND OF THE INVENTION

### Field of the Invention

The present disclosure relates to a semiconductor device.

### Description of the Background Art

For example, Japanese Patent Application Laid-Open No. 2001-223178 discloses a technique for suppressing the generation of voids caused by incorporation of Ar gas into a silicide film by using a metal that forms a silicide having many metal compositions in an initial silicide reaction, for example, Co, as a barrier metal in forming a silicide layer on a semiconductor substrate. According to this technique, it is possible to prevent the deterioration of contact resistance between the silicide film and the electrode formed thereon.

Incidentally, a phenomenon in which voids are formed by the aggregation of inert gas elements contained in a metal film by heat treatment has been reported in, for example, Peter Hatton, et al., “Inert gas bubble formation in magnetron sputtered thin-film CdTe solar cells”, Proc. Of the royal soc. A, vol 476, issue 2239.

In addition, WO 2021/246241 A discloses a technique of forming a keyhole-shaped (a shape having an inlet narrower than an internal space) recess in a cross-sectional view on a surface of an electrode to improve the joint strength between the electrode and an upper electrode thereon by an anchor effect.

In the technique disclosed in Japanese Patent Application Laid-Open No. 2001-223178, a uniformly dense silicide film is formed at the contact portion between the semiconductor substrate and the electrode, so that adhesion strength between the semiconductor substrate and the electrode can be increased. However, if the adhesion strength between the semiconductor substrate and the electrode is too high, breakdown caused by external stress is likely to extend to the active cell of the semiconductor substrate. This then causes a serious accident such as short-circuit breakdown.

### SUMMARY

An object of the present disclosure is to reduce the adhesion strength between an alloy layer and a metal film while preventing the deterioration of contact resistance between the alloy layer formed on the semiconductor layer and the metal layer thereon.

A semiconductor device according to the present disclosure includes a semiconductor substrate, an alloy layer containing a constituent element of the semiconductor substrate as a main component, and an upper metal layer formed on the alloy layer. A plurality of minute regions containing an inert gas is discretely arranged at an interface between the alloy layer and the upper metal layer. 90% or more of a plurality of the minute regions has an arc shape in which the opening is the widest portion.

According to the present disclosure, it is possible to alleviate the adhesion strength between the alloy layer and the metal film while preventing the deterioration of the contact resistance between the alloy layer formed on the semiconductor layer and the metal layer (upper metal layer) thereon.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a view showing the basic structure of the contact portion of a semiconductor device according to a first preferred embodiment;

FIGS. 2A to 2C are views for explaining a method of forming the contact portion of the semiconductor device according to the first preferred embodiment;

FIGS. 3A to 3C are views for explaining the method of forming the contact portion of the semiconductor device according to the first preferred embodiment;

FIG. 4 is a view showing a specific example of the contact portion of the semiconductor device according to the first preferred embodiment;

FIG. 5 is a view showing an atomic number contrast image of the contact portion of the semiconductor device according to the first preferred embodiment;

FIG. 6 is a view showing an atomic number contrast image of a conventional contact portion without a minute region;

FIG. 7 is an enlarged view of a portion near a minute region in the atomic number contrast image of FIG. 5;

FIG. 8 is a view showing an element map image of Si in the contact portion of the semiconductor device according to the first preferred embodiment;

FIG. 9 is a view showing an element map image of Ar in the contact portion of the semiconductor device according to the first preferred embodiment;

FIG. 10 is a diagram showing an EDX spectrum of the contact portion of the semiconductor device according to the first preferred embodiment; and

FIG. 11 is a view showing the structure of the contact portion of the semiconductor device according to the first preferred embodiment.

### DESCRIPTION OF THE PREFERRED EMBODIMENTS

### First Preferred Embodiment

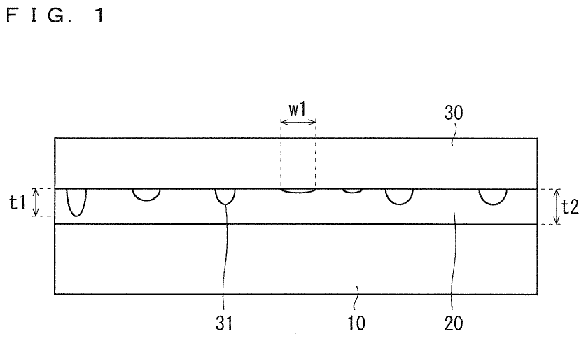

FIG. 1 is a view showing the basic structure of the contact portion of a semiconductor device according to a first preferred embodiment. As shown in FIG. 1, the “contact portion” in the present preferred embodiment refers to a portion where a semiconductor substrate 10 and an upper metal layer 30 are connected via an alloy layer 20.

The semiconductor substrate 10 contains, for example, a compound containing Si, SiC, or Ga as a constituent element. The alloy layer 20 is formed on the upper surface of the semiconductor substrate 10 and is made of an alloy containing a constituent element of the semiconductor substrate 10 as a main component. When the semiconductor substrate 10 is a wide band gap semiconductor such as SiC or GaN, a semiconductor device excellent in operation at a high voltage, a large current, and a high temperature is obtained as compared with the case of silicon.

On the surface portion of the semiconductor substrate 10, an n-type layer or a p-type layer containing a donor or an acceptor as a dopant may be selectively formed. The alloy layer 20 may be in contact with an n-type layer or a p-type layer or both formed on the semiconductor substrate 10. Further, the alloy layer 20 may be formed by alloying the surface portions of the n-type layer or the p-type layer or both of them formed on the semiconductor substrate 10.

The alloy layer 20 is formed by, for example, depositing a metal film (corresponding to a “metal film 21” to be described later) on the semiconductor substrate 10 by a sputtering method or a chemical vapor deposition (CVD) method and alloying the metal film and the semiconductor substrate 10 by subjecting them to a chemical reaction by a heat treatment. Therefore, the alloy layer 20 contains the constituent elements of the semiconductor substrate 10 and the constituent elements of the metal film before alloying as main components. As the metal film before alloying, for example, a film containing Ti, Ni, Co, or the like as a main component is assumed. When the semiconductor substrate 10 is Si or SiC, the alloy layer 20 is preferably a silicide compound.

The upper metal layer 30 is formed on the alloy layer 20. The upper metal layer 30 is made of, for example, Ti, Ni, W, Cu, Al, or an alloy (for example, TiN) containing one or more of Ti, Ni, W, Cu, Al, or the like and is formed by, for example, a sputtering method or a CVD method. Further above the upper metal layer 30, there may be another upper metal layer composed of a component different from that of the upper metal layer 30. Furthermore, a multilayer structure obtained by stacking a metal made of a different component, a metal of the same type as the upper metal layer 30, and the like may be formed on the upper metal layer 30.

A plurality of minute regions 31 containing an inert gas is discretely formed at an interface between the alloy layer 20 and the upper metal layer 30. The minute region 31 has a shape that erodes the alloy layer 20, that is, a shape that enters the alloy layer 20 side from the interface between the alloy layer 20 and the upper metal layer 30. In addition, the minute region 31 has an arc shape whose opening is the widest portion in cross-sectional view. Since the minute regions 31 having such a shape are discretely formed between the alloy layer 20 and the upper metal layer 30, it is possible to alleviate the adhesion strength between the alloy layer 20 and the upper metal layer 30 while preventing the deterioration of the contact resistance between the alloy layer 20 and the upper metal layer 30. The inert gas may be Ar, N₂, or another rare gas element.

Here, as shown in FIG. 1, the depth of the minute region 31 is defined as t1, the width of the minute region 31 is defined as w1, and the thickness of the alloy layer 20 is defined as t2. The thickness t2 of the alloy layer 20 is preferably, for example, 10 nm or more and 50 nm or less. The depth t1 of the minute region 31 is preferably, for example, 5 nm or more and less than t2. The width w1 of the minute region 31 is preferably, for example, 5 nm or more and less than 100 nm. It is desirable that 90% or more of a plurality of the minute regions 31 has an arc shape whose opening is the widest portion in cross-sectional view.

In the semiconductor device, the upper metal layer 30 is used as an electrode electrically connected to the semiconductor substrate 10 via the alloy layer 20. For example, when the semiconductor device is a semiconductor device for power control (so-called power device), the adhesion strength of the electrode can be an important design parameter in a stress test such as a power cycle (P/C) test or a heat cycle (H/C) test.

If the adhesion strength of the upper metal layer 30 as an electrode is too low, the upper metal layer 30 is peeled off in a stress test, and the life of the semiconductor device is reduced. However, if the adhesion strength of the upper metal layer 30 is too high, the breakdown during the stress test extends not to the interface between the upper metal layer 30 and the alloy layer 20 but to the inside of the semiconductor substrate 10. The breakdown of the inside of the semiconductor substrate 10 may short-circuit the semiconductor device. For example, when a semiconductor device holding a voltage of several hundred volts to several thousand volts is short-circuited, a serious breakdown of the entire system on which the semiconductor device is mounted is caused.

By applying the structure of the contact portion according to the first preferred embodiment to an electrode of the semiconductor device, the adhesion strength of the electrode can be controlled. By setting the adhesion strength of the electrode within a desired range, it is possible to keep the breakdown at the interface between the alloy layer 20 and the upper metal layer 30 without impairing the life in the stress test, and it is possible to suppress the short circuit of the semiconductor device.

Conventionally, there has been a problem that the contact resistance of the upper metal layer 30 is deteriorated by the formation of voids in the alloy layer 20. Since it was difficult to control the composition, shape, and size of a void, it was considered that the void should completely disappear.

The inventors of the technology according to the present disclosure have succeeded in discretely arranging the minute regions 31 different from the voids at the interface between the alloy layer 20 and the upper metal layer 30 by detailed analysis of the semiconductor manufacturing process.

As more preferable parameters for controlling the adhesion strength without deteriorating the contact resistance of the upper metal layer 30, the thickness t2 of the alloy layer 20 is preferably 30 nm or more, the width w1 of the minute region 31 is preferably less than 100 nm, and the depth t1 of the minute region 31 is preferably less than t2. In addition, the occupancy of the minute region 31 at the interface between the alloy layer 20 and the upper metal layer 30 is desirably less than 50%. The atomic concentration of the inert gas in the minute region 31 is desirably 0.5 wt % or more and less than 20.0 wt %, and the atomic density of the constituent element of the alloy layer 20 in the minute region 31 is desirably 80.0 wt % or more.

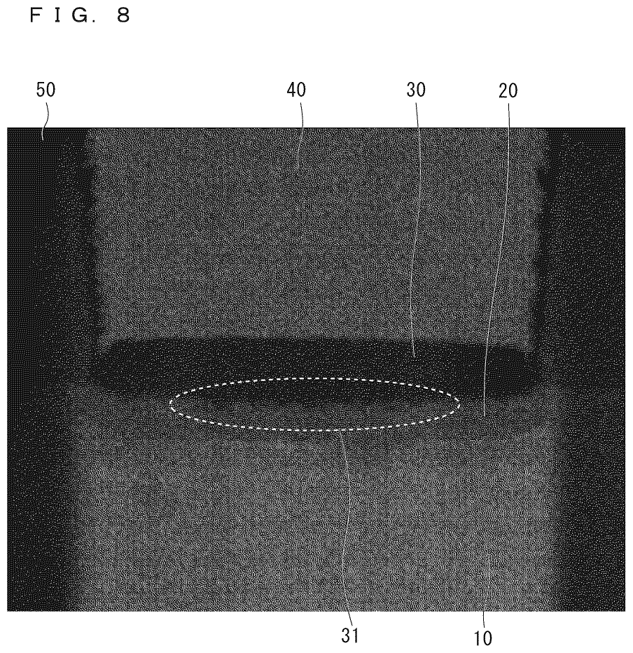

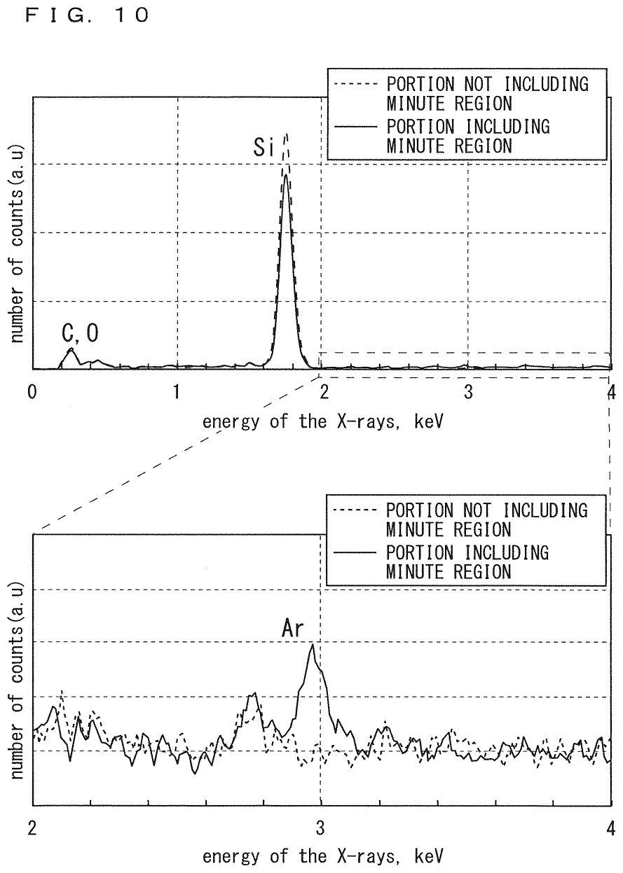

The atomic concentration of the minute region 31 may be a value quantitatively evaluated by a general elemental analysis method such as energy dispersive X-ray spectroscopy (EDX). In the elemental analysis method, in a case where an evaluation region is as small as the order of nm or the like, it is assumed that a value including a region other than the evaluation target is output, but there is no problem as long as the element in the minute region 31 can be detected as shown in FIGS. 8 and 10 to be described later.

If the width w1 of the minute region 31 is too wide, the substantial thickness of the alloy layer 20 decreases and the contact resistance deteriorates. In addition, when the depth t1 of the minute region 31 is too large, the upper metal layer 30 and the semiconductor substrate 10 come into contact with each other, and a favorable ohmic contact cannot be obtained, which also causes the deterioration of contact resistance. In addition, if the occupancy of the minute region 31 is too high, similarly to the case where the width w1 of the minute region 31 is too wide, the substantial thickness of the alloy layer 20 decreases and the contact resistance deteriorates.

In addition, when the minute region 31 is not formed at the interface between the alloy layer 20 and the upper metal layer 30, the adhesion strength of the upper metal layer 30 increases, and the breakdown easily extends to the semiconductor substrate 10 during the stress test. In addition, even in a case where the minute region 31 has a keyhole shape such as the concave portion in WO 2021/246241 A described above, the adhesion strength of the upper metal layer 30 becomes excessively high due to the anchor effect, so that the breakdown easily extends to the semiconductor substrate 10 during the stress test. Therefore, it is important to control the width, depth, density, shape, and position of the minute region 31 within preferable ranges.

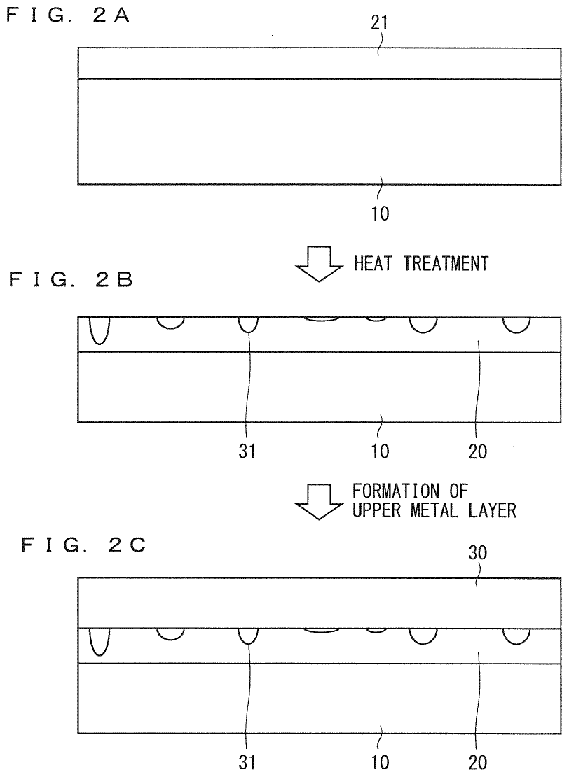

FIGS. 2A to 2C show a method of manufacturing the semiconductor device according to the first preferred embodiment, particularly, a method of forming the contact portion.

First, as shown in FIG. 2A, the metal film 21 to be a material for the alloy layer 20 is formed on the semiconductor substrate 10 by a sputtering method or a CVD method. Then, heat treatment is performed to chemically react the semiconductor substrate 10 with the metal film 21 to form the alloy layer 20. At this time, the minute region 31 can be formed on the surface of the alloy layer 20 as shown in FIG. 2B by using the following method.

Here, a case where the metal film 21 is formed by a sputtering method will be described. The sputtering method is generally a film forming method in which a chamber is filled with an inert gas at a certain ratio, the inert gas is turned into plasma, the plasma is caused to collide with a target metal, bonds between atoms of the target metal are physically cut to ionize (activate) metal atoms, and the metal atoms are deposited on the semiconductor substrate 10. The metal film 21 deposited on the semiconductor substrate 10 contains not only desired metal ions but also a trace amount of plasma-converted inert gas ions. In the conventional manufacturing method, the content of the inert gas ions is small, and the inert gas ions volatilize and disappear in the heat treatment for alloying the metal film 21, or are incorporated into the alloy layer 20 without being aggregated.

In the present preferred embodiment, by increasing the concentration of the inert gas contained in the pre-alloy metal film 21, the minute region 31 is formed on the surface of the alloy layer 20 as shown in FIG. 2B. In the minute region 31, the mass percent concentration of atoms constituting the alloy layer 20 is low, and the content of the inert gas is large. That is, the minute region 31 is a rough region in which the atomic density is reduced by the aggregation of the inert gas during the heat treatment.

Thereafter, as shown in FIG. 2C, a metal film is deposited on the alloy layer 20 including the minute region 31 to deposit the upper metal layer 30. After the upper metal layer 30 is formed, heat treatment may be performed.

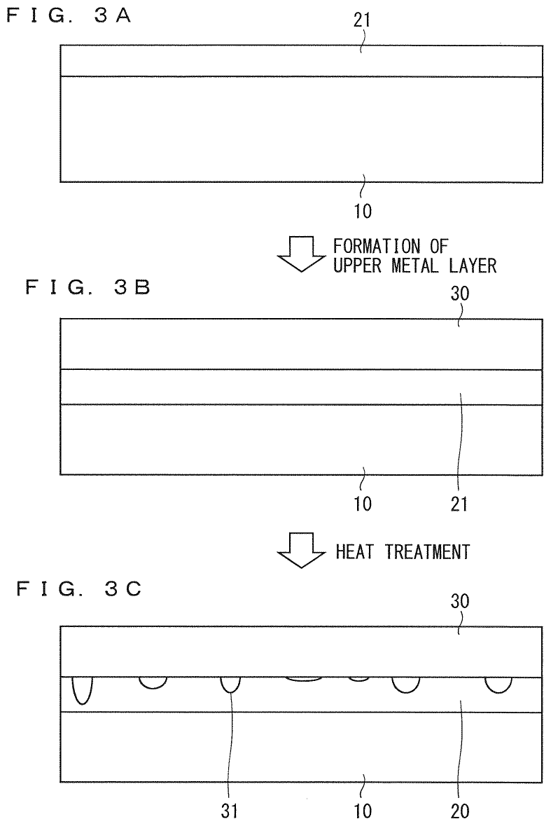

The alloying of the metal film 21 and the heat treatment for forming the minute regions 31 may be performed after the deposition of the upper metal layer 30. That is, first, as shown in FIG. 3A, the metal film 21 to be a material for the alloy layer 20 is formed on the semiconductor substrate 10, and then, as shown in FIG. 3B, the upper metal layer 30 is formed on the metal film 21. Thereafter, heat treatment may be performed to chemically react the semiconductor substrate 10 with the metal film 21 as shown in FIG. 3C to form the alloy layer 20 and to form the minute region 31 on the surface of the alloy layer 20.

The minute region 31 is common to voids in that the inert gas element contained in the metal film 21 before alloying is aggregated by heat treatment, but the minute region 31 is controlled in width, depth, density, position, atomic density, and the like, and is not a complete void.

The metal film 21 before alloying may be deposited using a CVD method. However, unlike the case of the sputtering method, an inert gas is not taken into the metal film 21. Therefore, after the metal film 21 is deposited, for example, an inert gas needs to be introduced into the metal film 21 by an ion implantation method or the like. Even in a case where an inert gas is introduced after the metal film 21 is deposited, the inert gas is aggregated when heat treatment is performed, and the minute region 31 is formed.

Next, a method of controlling the parameters of the minute region 31 will be described. Since the minute region 31 is formed by aggregation of inert gas atoms, it is necessary to control the amount of inert gas contained in the metal film 21 before alloying in order to control the parameters of the minute region 31.

For example, in order to control the amount of the inert gas taken into the metal film 21 when the metal film 21 is formed by the sputtering method, it is only required to perform adjustment of the pressure in the chamber, adjustment of the plasma density, adjustment of the pull-in voltage for active species to the semiconductor substrate 10, and the like. The pressure in the chamber can be adjusted by the flow rate of the inert gas, and the flow rate of the inert gas may be adjusted in a range of, for example, 1 sccm to 100 sccm. The plasma density can be adjusted by a DC bias which is one of the adjustment parameters, and the DC bias may be adjusted in a range of, for example, 1 kW to 50 kW. The pull-in voltage for the active species can be adjusted with an AC bias, and the AC bias may be adjusted, for example, in a range of 1 W to 1 kW. The temperature at the time of film formation may be adjusted, for example, in a range of room temperature to 500° C.

In addition, the thicker the metal film 21 before alloying is, the more the amount of inert gas atoms aggregated at the interface increases, and thus, it is preferable that the film thickness of the metal film 21 is thick. However, if the metal film 21 is too thick, the alloy layer 20 to be formed also becomes thick, the alloy layer 20 is formed deeper than the n-type layer or the p-type layer in the surface portion of the semiconductor substrate 10, and the contact resistance increases. Therefore, the thickness t2 of the alloy layer 20 is preferably, for example, 30 nm or more and 50 nm or less.

Furthermore, the condition of the heat treatment after the deposition of the metal film 21 before alloying can also be an important parameter. For example, when the heat treatment is performed at a high temperature for a long time, the aggregation of the inert gas is accelerated, and the minute region 31 becomes huge. Accordingly, the width and depth of the minute region 31 increase, and a desired shape cannot be obtained. As conditions of the heat treatment, it is desirable that the temperature is in the range of 700° C. to 900° C., and the time is in the range of 10 seconds to 120 seconds.

The parameters of the minute region 31 can be controlled by adjusting the above parameters.

The metal film 21 before alloying may be deposited using a CVD method. However, unlike the case of using the sputtering method, the inert gas is not taken in during the deposition of the metal film 21. Therefore, it is necessary to take in, for example, an inert gas by an ion implantation method or the like after the deposition of the metal film 21. Even in a case where an inert gas is introduced after the metal film 21 is deposited, the inert gas is aggregated when heat treatment is performed, and the minute region 31 is formed.

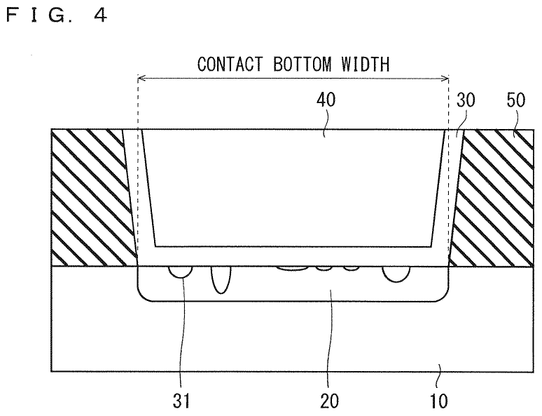

FIG. 4 is a specific example of the contact portion of the semiconductor device according to the first preferred embodiment and schematically shows a cross section of the emitter (or source) contact of the semiconductor device for power conversion. An interlayer insulating film 50 is formed on the semiconductor substrate 10. A contact hole reaching the semiconductor substrate 10 is formed in the interlayer insulating film 50, and the alloy layer 20 is formed on a surface portion of the semiconductor substrate 10 exposed at the bottom of the contact hole. The upper metal layer 30 is formed on the alloy layer 20, and the minute region 31 is formed at the interface between the alloy layer 20 and the upper metal layer 30. Furthermore, an upper metal layer 40 as a contact plug for embedding a contact hole is formed on the upper metal layer 30.

The semiconductor substrate 10 is, for example, a compound containing Si, SiC, or Ga. In addition, the alloy layer 20 is a silicide compound, an alloy mainly containing an element of the semiconductor substrate 10, or the like. The interlayer insulating film 50 is, for example, a TEOS film, a BPSG film, a thermal oxide film, or a multilayer film thereof, and is provided to ensure insulation with a gate electrode (not shown).

The bottom width of the contact hole formed in the interlayer insulating film 50 (the contact bottom width shown in FIG. 4) is, for example, on the order of submicron from 0.2 μm to 1.0 μm (inclusive), and the aspect ratio (that is, the thickness of the interlayer insulating film/the bottom width of the contact hole) with respect to the thickness of the interlayer insulating film 50 is, for example, 1.5 or more. Although not shown, an n-type or p-type emitter layer is selectively formed on the surface portion of the semiconductor substrate 10 at the bottom of the contact hole, and the alloy layer 20 is in contact with the emitter layer.

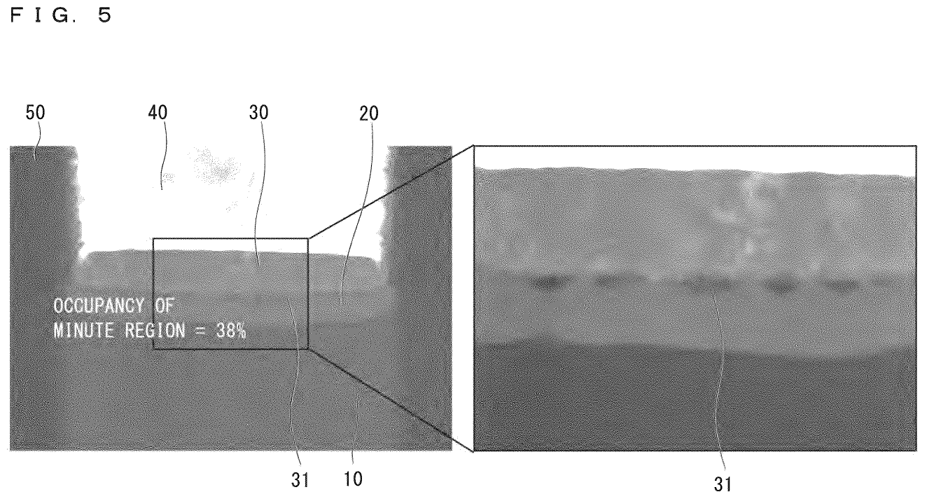

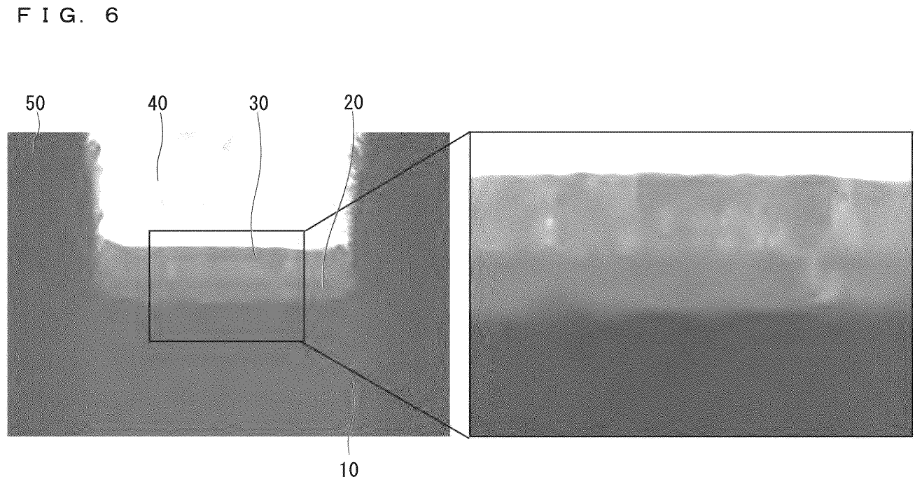

FIG. 5 is an atomic number contrast image obtained by a cross-sectional TEM of the contact portion of the semiconductor device according to the first preferred embodiment having the structure of FIG. 4. In the atomic number contrast image, a portion having a lower atomic density is darker in black. Therefore, the minute region 31 is shown as a local dark black region. It can be confirmed from FIG. 5 that the minute regions 31 are discretely formed. FIG. 6 shows an atomic number contrast image of a conventional contact portion having no minute region as a comparative example.

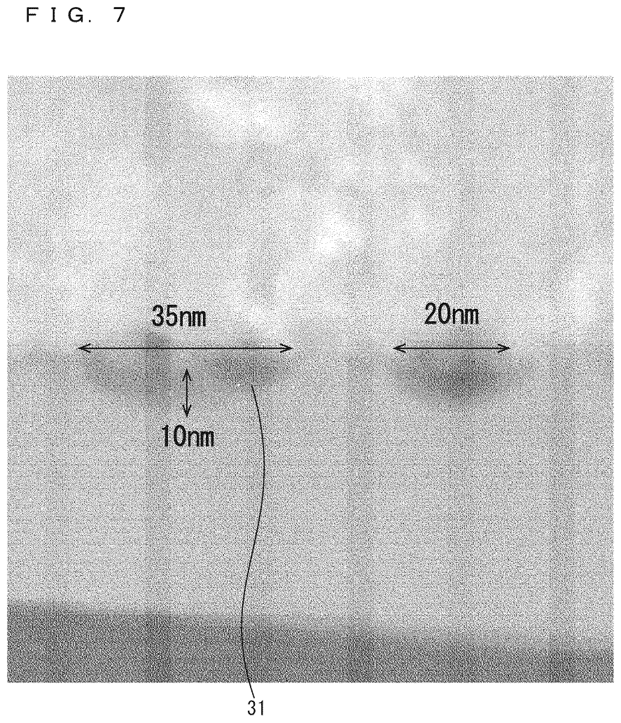

FIG. 7 is an enlarged view and dimensions of a portion near the minute region 31 in the atomic number contrast image of FIG. 5. By adjusting the inert gas element contained in the metal film 21 before alloying and the conditions of heat treatment, the minute region 31 having a width of 35 nm and a depth of 10 nm with a reduced atomic concentration has been successfully formed. The dimensions of the upper metal layer 30 shown in FIG. 7 are merely an example.

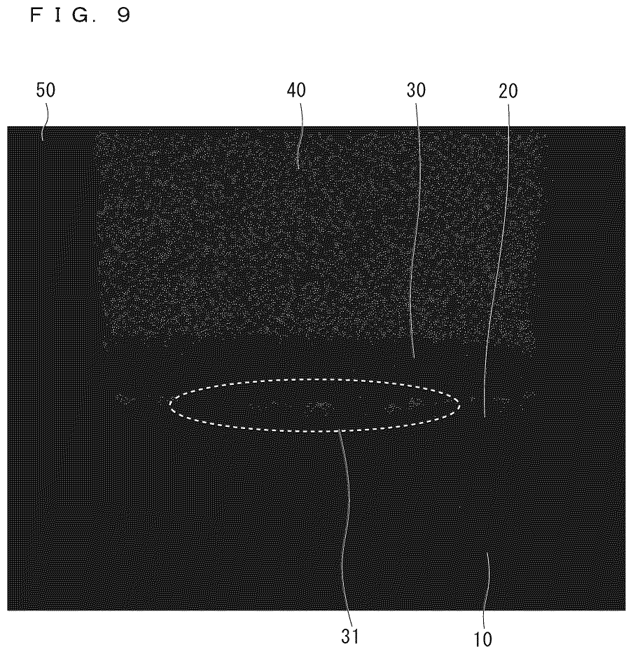

FIGS. 8 and 9 show element map images of the contact portion of the semiconductor device according to the first preferred embodiment having the structure of FIG. 4. FIG. 8 is an element map image of Si, and FIG. 9 is an element map image of Ar. The constituent elements of the upper metal layer 30 do not include Si, and the constituent elements of the alloy layer 20 and the semiconductor substrate 10 include Si. Therefore, in the elemental map image of Si shown in FIG. 8, the upper metal layer 30 is drawn with a dark contrast. In a boundary portion between the alloy layer 20 and the upper metal layer 30 (the region surrounded by the white broken line), the minute region 31 in which the atomic concentration of Si has decreased is drawn locally with a dark contrast. Although bright contrast appears in a portion of the upper metal layer 40 not containing Si, it is confirmed from the EDX spectrum that this is due to background noise.

On the other hand, in the element map image of Ar shown in FIG. 9, the minute region 31 in which the atomic concentration of Ar is increased is drawn with locally bright contrast at the boundary portion (the region surrounded by the white broken line) between the alloy layer 20 and the upper metal layer 30. Also in FIG. 9, it is confirmed that the bright contrast of the portion of the upper metal layer 40 is background noise.

FIG. 10 is a diagram showing EDX spectra which are original data of the element map images of FIGS. 8 and 9. Each broken line is the spectrum of the portion of the alloy layer 20 not including the minute region 31, and each solid line is the spectrum of the portion of the alloy layer 20 including the minute region 31. In the portion including the minute region 31, the peak intensity of Si, which is a constituent element of the alloy layer 20, is reduced by about 3.1% with respect to the portion not including the minute region 31. In addition, Ar which is an element of the inert gas is significantly detected in a portion including the minute region 31.

From FIGS. 8, 9, and 10, it can be confirmed that the minute region 31 is a region where the concentration of the constituent element of the alloy layer 20 is small and the atomic concentration of the inert gas is high.

### Second Preferred Embodiment

In the second preferred embodiment, the minute region 31 described in the first preferred embodiment is applied to an electrode formed on an interlayer insulating film 50.

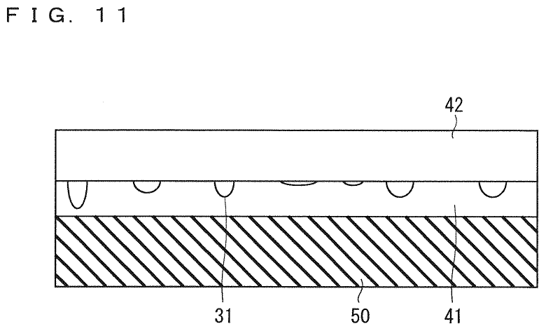

FIG. 11 is a diagram showing the basic structure of the contact portion of a semiconductor device according to the second preferred embodiment. As shown in FIG. 11, the “contact portion” in the present preferred embodiment refers to a portion where a lower metal layer 41 formed on the interlayer insulating film 50 and the upper metal layer 42 thereon are connected. The interlayer insulating film 50 is, for example, an oxide film.

In the contact portion of the semiconductor device according to the second preferred embodiment, a minute region 31 is formed at the interface between the lower metal layer 41 and the upper metal layer 42. The minute region 31 has a shape that erodes the lower metal layer 41, that is, a shape that enters the lower metal layer 41 side from the interface between the lower metal layer 41 and the upper metal layer 42. It is desirable that 90% or more of a plurality of the minute regions 31 has an arc shape whose opening is the widest portion in cross-sectional view.

In addition, the minute region 31 has an arc shape whose opening is the widest portion in cross-sectional view. The width, depth, density, shape, position, and the like of the minute region 31 are the same as those in the first preferred embodiment. However, the lower metal layer 41 in which the minute region 31 is formed is formed on the interlayer insulating film 50, and is not alloyed with a semiconductor substrate 10. Therefore, the lower metal layer 41 does not contain the constituent element of the semiconductor substrate 10, and the constituent element of the semiconductor substrate 10 is not contained in the minute region 31. The atomic concentration of the constituent element of the lower metal layer 41 in the minute region 31 is desirably 80.0 wt % or more.

The minute region 31 can be formed by applying heat treatment to the lower metal layer 41 incorporating an inert gas. The method of forming the contact portion is similar to the method of forming the contact portion (FIGS. 2A to 2C and 3A to 3C) described in the first preferred embodiment, and thus a description thereof is omitted here. The width, depth, density, shape, position, and the like of the minute region 31 are controlled by adjusting an inert gas element contained in the lower metal layer 41 and conditions for heat treatment.

In the second preferred embodiment, it is possible to alleviate adhesion strength between the lower metal layer 41 and the upper metal layer 42 formed on the interlayer insulating film 50 while preventing the deterioration of contact resistance between the lower metal layer and the upper metal layer. Even when the electrode on the interlayer insulating film 50 is peeled off during a stress test, it is possible to suppress the extension of the breakdown into the semiconductor substrate 10 without impairing the life in the stress test by adjusting the adhesion strength to an appropriate adhesion strength.

Note that the respective preferred embodiments can be freely combined and can be modified and omitted as needed.

### APPENDIX

Hereinafter, various aspects of the present disclosure will be collectively described as appendixes.

### Appendix 1

A semiconductor device comprising:
a semiconductor substrate;
an alloy layer containing a constituent element of the semiconductor substrate as a main component; and
an upper metal layer formed on the alloy layer,
wherein a plurality of minute regions containing an inert gas is discretely arranged at an interface between the alloy layer and the upper metal layer, and
not less than 90% of a plurality of the minute regions has an arc shape whose opening is the widest portion.

### Appendix 2

The semiconductor device according to appendix 1, wherein an atomic concentration of a constituent element of the alloy layer in the minute region is not less than 80 wt %.

### Appendix 3

The semiconductor device according to appendix 1 or 2, wherein
the alloy layer has a thickness of not less than 30 nm,
the minute region has a width of less than 100 nm, and
the minute region has a depth of less than the thickness of the alloy layer.

### Appendix 4

The semiconductor device according to any one of appendixes 1 to 3, wherein an occupancy of the minute region at an interface between the alloy layer and the upper metal layer is less than 50%.

### Appendix 5

The semiconductor device according to any one of appendixes 1 to 4, further comprising:
an interlayer insulating film formed on the semiconductor substrate; and
a contact hole formed in the interlayer insulating film and reaching the semiconductor substrate,
wherein the alloy layer and the upper metal layer are formed on the semiconductor substrate at a bottom of the contact hole, and
a bottom width of the contact hole ranges from not less than 0.2 μm to not more than 1.0 μm.

### Appendix 6

The semiconductor device according to appendix 5, wherein an aspect ratio between the bottom width of the contact hole and a thickness of the interlayer insulating film is not less than 1.5.

### Appendix 7

The semiconductor device according to any one of appendixes 1 to 6, wherein an atomic concentration of the inert gas in the minute region is not less than 0.5 wt % and less than 20.0 wt %.

### Appendix 8

The semiconductor device according to any one of appendixes 1 to 7, wherein the inert gas is Ar or N₂.

### Appendix 9

The semiconductor device according to any one of appendixes 1 to 8, wherein the semiconductor substrate is made of a compound containing Si, SiC, or Ga.

### Appendix 10

The semiconductor device according to any one of appendixes 1 to 8, wherein
the semiconductor substrate is made of Si or SiC, and
the alloy layer is a silicide compound containing Ti or Ni.

### Appendix 11

The semiconductor device according to any one of appendixes 1 to 10, wherein the upper metal layer is made of a metal containing Ti, W, or Al as a main component or a multilayer structure of a plurality of metals containing Ti, W, or Al as a main component.

### Appendix 12

A semiconductor device comprising:
a lower metal layer; and
an upper metal layer formed on the lower metal layer,
wherein a plurality of minute regions containing an inert gas is discretely arranged at an interface between the lower metal layer and the upper metal layer, and
not less than 90% of a plurality of the minute regions has an arc shape whose opening is the widest portion.

### Appendix 13

The semiconductor device according to appendix 12, wherein an atomic concentration of a constituent element of the lower metal layer in the minute region is not less than 80 wt %.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate;
an alloy layer containing a constituent element of the semiconductor substrate as a main component; and
an upper metal layer formed on the alloy layer,
wherein a plurality of minute regions containing an inert gas is discretely arranged at an interface between the alloy layer and the upper metal layer, and
not less than 90% of a plurality of the minute regions has an arc shape whose opening is the widest portion.

2. The semiconductor device according to claim 1, wherein an atomic concentration of a constituent element of the alloy layer in the minute region is not less than 80 wt %.

3. The semiconductor device according to claim 1, wherein
the alloy layer has a thickness of not less than 30 nm,
the minute region has a width of less than 100 nm, and
the minute region has a depth of less than the thickness of the alloy layer.

4. The semiconductor device according to claim 1, wherein an occupancy of the minute region at an interface between the alloy layer and the upper metal layer is less than 50%.

5. The semiconductor device according to claim 1, further comprising:
an interlayer insulating film formed on the semiconductor substrate; and
a contact hole formed in the interlayer insulating film and reaching the semiconductor substrate,
wherein the alloy layer and the upper metal layer are formed on the semiconductor substrate at a bottom of the contact hole, and
a bottom width of the contact hole ranges from not less than 0.2 μm to not more than 1.0 μm.

6. The semiconductor device according to claim 5, wherein an aspect ratio between the bottom width of the contact hole and a thickness of the interlayer insulating film is not less than 1.5.

7. The semiconductor device according to claim 1, wherein an atomic concentration of the inert gas in the minute region is not less than 0.5 wt % and less than 20.0 wt %.

8. The semiconductor device according to claim 1, wherein the inert gas is Ar or N₂.

9. The semiconductor device according to claim 1, wherein the semiconductor substrate is made of a compound containing Si, SiC, or Ga.

10. The semiconductor device according to claim 1, wherein
the semiconductor substrate is made of Si or SiC, and
the alloy layer is a silicide compound containing Ti or Ni.

11. The semiconductor device according to claim 1, wherein the upper metal layer is made of a metal containing Ti, W, or Al as a main component or a multilayer structure of a plurality of metals containing Ti, W, or Al as a main component.

12. A semiconductor device comprising:
a lower metal layer; and
an upper metal layer formed on the lower metal layer,
wherein a plurality of minute regions containing an inert gas is discretely arranged at an interface between the lower metal layer and the upper metal layer, and
not less than 90% of a plurality of the minute regions has an arc shape whose opening is the widest portion.

13. The semiconductor device according to claim 12, wherein an atomic concentration of a constituent element of the lower metal layer in the minute region is not less than 80 wt %.
